(19) United States
(12) Patent Application Publication
(10) Pub. No.: US 2009/0122824 A1
(43) Pub. Date: May 14, 2009

(54) SEMICONDUCTOR LASER APPARATUS

(75) Inventors: Hidekazu Kawanishi, Kanagawa (JP); Yuichi Hamaguchi, Tokyo (JP)

Correspondence Address: SONNENSCHEIN NATH & ROSENTHAL LLP, P.O. BOX 061080, WACKER DRIVE STATION, SEARS TOWER, CHICAGO, IL, 60606-1080, US

(73) Assignee: SONY CORPORATION, Tokyo (JP)

(21) Appl. No.: 12/261,499

(22) Filed: Oct. 30, 2008

(30) Foreign Application Priority Data
Oct. 31, 2007 (JP) 2007-283156

(51) Int. Cl. H01S 5/026

(52) U.S. Cl. 372/50.11

(57) ABSTRACT

A semiconductor laser apparatus having a first clad layer, a first guide layer, an active layer, a second guide layer, and a second clad later formed in the order listed is disclosed. A layer serving as an optical waveguide is formed between the first clad layer and the second clad layer and wherein the layer serving as an optical waveguide is formed with such a thickness that not only light of a fundamental mode but also light of a higher-order mode is guided. An absorption layer absorbing the light of a higher-order mode is formed in a position to suppress only the oscillation of the light of a higher-order mode, the absorption layer being formed as a layer forming part of the layer to serve as an optical waveguide.

### CROSS REFERENCES TO RELATED APPLICATIONS

The present invention contains subject matter related to Japanese Patent Application JP 2007-283156 filed in the Japanese Patent Office on Oct. 31, 2007, the entire contents of which being incorporated herein by reference.

### BACKGROUND OF THE INVENTION

1. Field of the Invention

The present invention relates to a semiconductor laser apparatus which emits laser light.

2. Description of the Related Art

In general, a semiconductor laser apparatus has a multi-layer structure in which an n-clad layer, an n-guide layer, an active layer, a p-guide layer, and a p-clad layer are formed one over another in the order listed on a substrate. The apparatus further includes a negative electrode and a positive electrode disposed to sandwich the multi-layer structure. When a current is injected through the negative electrode and the positive electrode, a great number of electrons move from the n (negative) side toward the p (positive) side, and a great number of holes (to be coupled with the electrons) are injected from the p side toward the n side. Coupling takes place between the electrons and holes thus concentrated in a region near the active layer that is a p-n junction, and light is induction-emitted when the coupling takes place. The induction-emitted light is confined in the guide layer to undergo repetitive reflections, and the region between the n-clad layer and the p-clad layer serves as an optical waveguide. Thus, the light is emitted as laser light from a cleavage surface.

Recently, semiconductor laser apparatus having a so-called LOC (Large Optical Cavity) structure are widely used as ultra high power (e.g., Watt-class) semiconductor laser apparatus, in particular, broad area type semiconductor laser apparatus used for processing and printing applications which impose no particular requirement for single mode properties in a lateral direction. In a semiconductor laser apparatus having an LOC structure, the thickness of a guide layer region (a multi-layer section formed by an n-guide layer, an active layer, and a p-guide layer) acting equivalently to a core of an optical waveguide is made very large to suppress bleed-through of light into a clad layer. Thus, absorption of free electrons by the clad layer and absorption of light by a metal layer provided outside the clad layer is suppressed to achieve improved light output (for example, see IEEE Journal of Selected Topics in Quantum Electronics, vol. 7, No. 2, March/April 2001, pp. 143-148 (Non-Patent Document 1)).

### SUMMARY OF THE INVENTION

In a semiconductor laser apparatus having an LOC structure, since a layer section serving as an optical waveguide has a quite large thickness, the optical waveguide has a structure through which not only light of a fundamental mode but also light of a higher-order mode can be guided, although optical absorption at a clad layer and outside the clad layer can be suppressed. The light of a fundamental mode has a light intensity distribution which is in the form of a single-peaked curve when viewed in the stacking direction of the layers, and the position of the peak coincides with the position of an active layer. The light of a higher-order mode has a light intensity distribution which is in the form of a curve having a plurality of peaks when viewed in the stacking direction of the layers. Particularly, the light of a higher-order mode in this description is light having peaks one of which is in positional coincidence with the position of an active layer. The reason is that light is not oscillated or emitted as laser light without a peak in positional coincidence with an active layer.

Light of a higher-order mode as thus described can be generated as a result of an increase in the thickness of the region of layers to serve as an optical waveguide, and this is a characteristic unique to semiconductor laser apparatus having an LOC structure. Light of a higher-order mode results in a light intensity distribution which is more dispersed than that obtained from light of a fundamental mode, and it may constitute a factor which can degrade a characteristic desired for a semiconductor laser apparatus having an LOC structure, i.e., improved light output.

In this regard, as described in Non-Patent Document 1, the thickness of clad layers may be decreased to increase loss of light of a higher-order mode attributable to scattering of the same out of an optical waveguide, whereby the light of a higher-order mode can be suppressed. This is a method of suppressing oscillation of light of a higher-order mode by imparting greater loss to the higher-order mode utilizing the fact that light of a higher-order mode has more components bleeding through and exiting an optical waveguide compared to light of a fundamental mode. However, such a method also results in increases in scattering loss and absorption loss of light of a fundamental mode, although the loss is small. As a result, according to the method, desired characteristics of a semiconductor laser apparatus having an LOC structure can be degraded.

Under the circumstance, it is desirable to provide a semiconductor laser apparatus in which an improvement of light output that is a desired characteristic unique to an LOC structure can be achieved by suppressing oscillation of light of a higher-order mode even when layers to serve as an optical waveguide are formed with such a thickness that not only light of a fundamental mode but also light of a higher-order mode can be guided.

According to an embodiment of the invention, there is provided a semiconductor laser apparatus including a first clad layer, a first guide layer, an active layer, a second guide layer, and a second clad later formed in the order listed. A layer serving as an optical waveguide is formed between the first clad layer and the second clad layer, and the layer serving as an optical waveguide is formed with such a thickness that not only light of a fundamental mode but also light of a higher-order mode is guided. As a layer forming part of the layer to serve as an optical waveguide, an absorption layer absorbing the light of a higher-order mode is formed in a position to suppress only the oscillation of the light of a higher-order mode.

In the semiconductor laser apparatus having the above-described configuration, the absorption layer absorbing the light of a higher-order mode is formed in positions to suppress only the oscillation of the light of a higher-order mode. The absorption layer is formed in such positions that only the oscillation of light of a higher-order mode will be suppressed. The positions to suppress only the oscillation of light of a higher-order mode may be positions corresponding to at least one of peak positions in the light intensity distribution of the light of a higher-order mode excluding the peak position in positional coincidence with the active layer. A position corresponding to a peak position is not necessarily a position exactly corresponding to a peak position, and it may include a position corresponding to a position in the vicinity of the peak position. When the absorption layer is formed in such positions, the oscillation of a higher-order mode requires a gain greater than that required when no absorption layer is formed. Therefore, the oscillation of light of a higher-order mode is suppressed by forming the absorption layer. Meanwhile, what is suppressed is only the oscillation of light of a higher-order mode. Since the absorption layer is disposed in positions where light of a fundamental mode has a low light intensity, increase in an oscillation threshold for the light of a fundamental mode can be minimized.

According to the embodiment of the invention, even when a layer serving as an optical waveguide is formed with such a thickness that not only light of a fundamental mode but also light of a higher-order mode is guided, the oscillation of the light of a higher-order mode is suppressed by forming an absorption layer. On the other hand, the light of a fundamental mode does not undergo oscillation beyond a required level and suffers from substantially no loss of light intensity as a result of the formation of the absorption layer. It is therefore possible to achieve improved light output that is a desirable characteristic unique to an LOC structure while suppressing oscillation of the light of a higher-order mode.

### BRIEF DESCRIPTION OF THE DRAWINGS

FIG. 1 is an illustration showing an exemplary configuration of a multi-layer structure of a semiconductor laser apparatus according to an embodiment of the invention;

FIG. 2 is an illustration showing specific examples of a refractive index distribution and light intensity distributions obtained by the multi-layer structure of the semiconductor laser apparatus according the embodiment of the invention;

FIG. 3 is a graph showing a specific example of a relationship between oscillation wavelengths and equivalent refractive indices of light;

FIG. 4 is an illustration showing a relationship between oscillation wavelengths of light and the period of a diffraction grating; and

FIGS. 5A and 5B are illustrations showing an example of steps of manufacturing the semiconductor laser apparatus.

### DETAILED DESCRIPTION OF THE INVENTION

A semiconductor laser apparatus according to an embodiment of the invention will now be described with reference to the drawings.

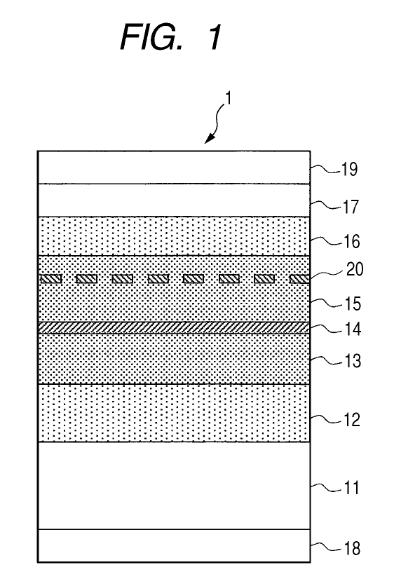

FIG. 1 is an illustration showing an exemplary configuration of a multi-layer structure of a semiconductor laser apparatus 1 according to an embodiment of the invention. The semiconductor laser apparatus 1 described here has a multi-layer structure as illustrated to serve as a semiconductor crystal element section for emitting light. Specifically, the apparatus has a multi-layer structure provided by forming an n-clad layer 12 to serve as a first clad layer, an n-guide layer 13 to serve as a first guide layer, an active layer 14, a p-guide layer 15 to serve as a second guide layer, a p-clad layer 16 to serve as a second clad layer, and a contact layer 17 in the order listed on a substrate 11. The apparatus further includes a negative electrode 18 and a positive electrode 19 disposed to sandwich the multi-layer structure.

For example, an n-GaAs substrate having a thickness of 100 μm may be used as the substrate 11. The n-clad layer 12 may be a film of n-(A10.2Ga0.8)0.51In0.49P formed with a thickness of 600 nm. The n-guide layer 13 may be a film of n-Ga0.51In0.49P formed with a thickness of 650 nm. The active layer 14 may be a film of i-In0.08Ga0.92As formed with a thickness of 9 nm. The p-guide layer 15 may be a film of p-Ga0.51In0.49P formed with a thickness of 650 nm. The p-clad layer 16 may be a film of p-(Al0.2Ga0.8)0.51In0.49P formed with a thickness of 600 nm. The contact layer 17 may be a film of p+GaAs formed with a thickness of 200 nm. Both of the negative electrode 18 and the positive electrode 19 may be provided by forming Ti, Pt, and Au films with thicknesses of 50 nm, 50 nm, and 100 nm, respectively. Obviously, the above film configurations and thicknesses are merely shown as specific examples.

In the semiconductor laser apparatus 1 having such a multi-layer structure, layers to serve as waveguide for light emitted by the semiconductor laser apparatus 1 are formed between the n-clad layer 12 and the p-clad layer 16. Specifically, a multy-layer section formed by the n-guide layer 13, the active layer 14, and the p-guide layer 15 is a layered section which acts equivalently to a core of an optical waveguide.

Referring to the thickness of the multy-layer section formed by the n-guide layer 13, the active layer 14, and the p-guide layer 15 or the layered section to serve as an optical waveguide, for example, the n-guide layer 13, the active layer 14, and the p-guide layer 15 have respective thicknesses of 650 nm, 9 nm, and 650 nm which total 1309 nm. The section therefore has a thickness which is much greater than that of a corresponding section of a semiconductor laser apparatus having an ordinary configuration (the corresponding layer section having a total thickness on the order of several tens nm). That is, the semiconductor laser apparatus 1 of the present embodiment has an LOC structure in which a layered section serving as an optical waveguide is formed with a very large thickness (for example, the guide layer on each side of the section has a thickness of 600 nm or more).

In the semiconductor laser apparatus 1 having an LOC structure, since the layered section serving as an optical waveguide is formed with a very large thickness, not only light of a fundamental mode but also light of a higher-order mode may be guided by the layered section.

The fundamental mode and the higher-order mode will now be described by showing specific examples thereof.

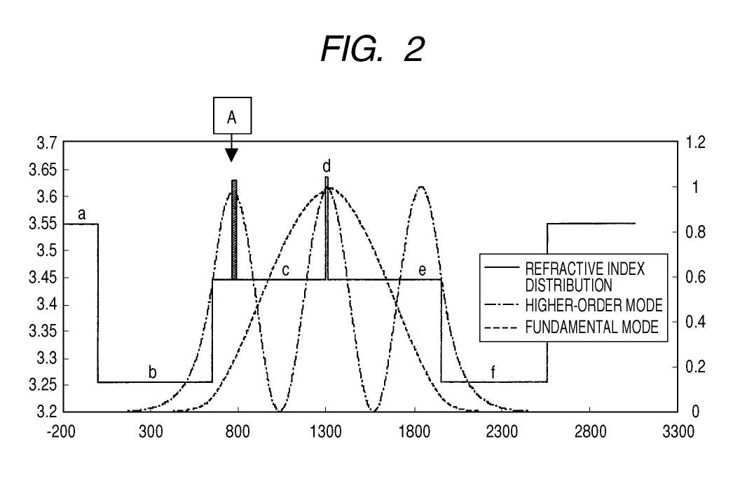

FIG. 2 is an illustration showing specific examples of a refractive index distribution and light intensity distributions obtained by the multi-layer structure of the semiconductor laser apparatus according to the embodiment of the invention.

The horizontal axis of FIG. 2 represents thicknesses of the multi-layer structure. More specifically, the axis represents integrated values of the layer thicknesses with reference to the boundary between the p-clad layer 16 and the contact layer 17 (the boundary having a thickness value “0”), the direction of approaching the substrate 11 being the direction of “positive” integration.

The vertical axis on the left side of FIG. 2 represents refractive index values. More specifically, the axis represents refractive index values measured on light having a wavelength of 940 nm.

Therefore, a distribution of refractive indices in the stacking direction of the layers forming the multi-layer structure is found from correspondences between the horizontal and vertical axes (indicated by the solid line in the figure). Specifically, the contact layer 17 provided in the form of a p+GaAs film has a refractive index of 3.549973 (indicated by a in the figure). The p-clad layer 16 provided in the form of a p-(Al0.2Ga0.8)0.51In0.49P film has a refractive index of 3.25451 (indicated by b in the figure). The p-guide layer 15 provided in the form of a p-Ga0.51In0.49P film has a refractive index of 3.446432 (indicated by c in the figure). The active layer 14 provided in the form of an i-In0.08Ga0.92As film has a refractive index of 3.63421 (indicated by d in the figure). The n-guide layer 13 provided in the form of an n-Ga0.51In0.49P film has a refractive index of 3.446432 (indicated by e in the figure). The n-clad layer 12 provided in the form of an n-(Al0.2Ga0.8)0.51In0.49P film has a refractive index of 3.25451 (indicated by f in the figure).

The vertical axis on the right side of FIG. 2 represents relative light intensity values. Since the values represent relative light intensities, they are values normalized such that a peak position has a value “1”. A distribution of relative light intensities in the stacking direction of the layers forming the multi-layer structure is found from correspondences between the vertical axis on the right side of the figure and the horizontal axis described above.

However, in the semiconductor laser apparatus 1 having an LOC structure, the layered section serving as an optical waveguide is formed with a very large thickness, and the layered section can therefore guide not only light of a fundamental mode but also light of a higher-order mode. Therefore, the relative light intensity distribution in the layer stacking direction may include a distribution of light of a fundamental mode (see the broken line in the figure) and a distribution of light of a higher-order mode (see the chain line in the figure).

Referring to light of a fundamental mode, as shown in the illustration, a light intensity distribution of the light in the layer stacking direction is in the form of a single-peaked curve, and the position of the peak coincides with the position of the active layer 14. Light of a fundamental mode as thus described is similar to light oscillated by a semiconductor laser apparatus having an ordinary configuration (in which a layered section serving as an optical waveguide has a total thickness on the order of several tens nm).

Light of a higher-order mode is unique to an LOC structure, and it can be generated because the layered section serving as an optical waveguide is formed with a very large total thickness. A light intensity distribution of light of a higher-order mode in the layer stacking direction is in the form of a curve having a plurality of peaks, and the position of one of the peaks coincides with the position of the active layer 14. More specifically, as shown in the illustration, the distribution may be in the form of a curve having three peaks, and the position of the peak in the middle coincides with the position of the active layer 14. The term “light of a hider-order mode” used in this specification does not apply to light of a higher-order mode having a plurality of peaks but having no peak in positional coincidence with the active layer 14, e.g., light of the first-order mode having two peaks or light of the third-order mode having four peaks. Although the illustration shows light of the second-order mode having three peaks as a specific example of light of a higher-order mode, light having an odd number (five or more) of peak positions (such as light of the fourth-order mode) may be guided depending on the total thickness of the layered section serving as an optical waveguide.

Light of a higher-order mode as thus described results in a light intensity distribution which is more dispersed than that of light of a fundamental mode. For this reason, it is not preferable that light of a higher-order mode is guided through the layered section serving as an optical waveguide in order to achieve an improvement in light output that is a characteristic desired for the LOC structure.

For this reason, as shown in FIG. 1, the semiconductor laser apparatus 1 of the present embodiment includes an absorption layer 20 formed between the n-clad layer 12 and the p-clad layer 16 as a layer forming part of the layers to serve as an optical waveguide, the absorption layer absorbing light of a higher-order mode to suppress oscillation of the light. For example, a film of In0.08Ga0.92As (which has a band gap wavelength of 950 nm) having a thickness of 20 nm may be formed as the absorption layer 20.

The absorption layer 20 is formed in such positions that only the oscillation of light of a higher-order mode will be suppressed. The positions to suppress only the oscillation of light of a higher-order mode may be positions corresponding to at least one of peak positions in the light intensity distribution of the light of a higher-order mode excluding the peak position which is in positional coincidence with the active layer 14. Since what is to be suppressed is “only” the light of a higher-order mode, the peak position in the light intensity distribution of the light of a fundamental mode (the peak position in positional coincidence with the active layer 14) is excluded. Since “at least one” of other peak positions is to be suppressed, the absorption layer 20 may be formed in any one of the other peak positions or in each of the plurality of positions. The position “corresponding to” a peak position may be a position which coincides with the apex of the peak position. Alternatively, the position may be a position in the vicinity of the peak position (e.g., a position in a range in which relative light intensity is equal to or higher than two-thirds of the peak value). Specifically, the absorption layer 20 extending periodically in the direction perpendicular to the oscillator direction (i.e., in the horizontal direction in FIG. 1) is formed.

More specifically, the position to suppress only the oscillation of light of a higher-order mode may be a position which coincides with one peak position in the light intensity distribution of light of a higher-order mode and which is offset by 538 nm from the center of the thickness of the active layer 14 toward the reference for integrated thickness values (the boundary between the p-clad layer 16 and the contact layer 17) when viewed in the layer stacking direction (see the arrow A in the figure).

When the absorption layer 20 is formed in such positions, the light of a higher-order mode has a light intensity relatively higher than the light intensity of the light of a fundamental mode in the positions where the layer is formed. The light of a higher-order mode can be more significantly absorbed, and the oscillation of the light of a higher-order mode can be suppressed accordingly. That is, the semiconductor laser apparatus 1 having the absorption layer 20 formed in such positions requires a greater gain to oscillate the higher-order mode than an apparatus without the absorption layer 20, and the oscillation of the light of the higher-order mode is consequently suppressed. Only the oscillation of the light of a higher-order mode is suppressed, and increase in an oscillation threshold for the light of a fundamental mode is minimized because the light has a low intensity in the positions where the absorption layer 20 is formed.

In the semiconductor laser apparatus 1 of the present embodiment, since an LOC structure is used, the multi-layer section formed by the n-guide layer 13, the active layer 14, and the p-guide layer 15 or the layered section serving as an optical waveguide is formed with such a thickness that not only light of a fundamental mode but also light of a higher-order mode can be guided. However, the oscillation of the higher-order mode light is suppressed by forming the absorption layer 20. The absorption layer 20 is formed in such positions that only the oscillation of the light of a higher-order mode is suppressed as described above. Therefore, the light of a fundamental mode does not undergo oscillation beyond a required level and suffers from substantially no loss of light intensity as a result of the formation of the absorption layer 20. Thus, the semiconductor laser apparatus 1 can provide improved light output that is a desirable characteristic unique to an LOC structure while suppressing oscillation of higher-order mode light.

The absorption layer 20 having the above-described effect may be in the form of what is called a solid film as long as it is formed in such positions that only oscillation of the higher-order mode light is suppressed as described above. The absorption layer 20 may alternatively be formed as described below in order to provide the semiconductor laser apparatus 1 with improved light output, in other words, to minimize loss of light intensity of the fundamental mode while suppressing the oscillation of the higher-order mode light.

The absorption layer 20 may be provided in the form of a diffraction grating having a predetermined period as shown in FIG. 1. A diffraction grating is an optical element which picks up beams of light having a particular wavelength from light that is a mixture of beams having various wavelengths. More particularly, a diffraction grating includes a multiplicity of elongate slits arranged in parallel with each other, and beams having a particular wavelength are obtained at particular angles utilizing diffraction and interference of beams entering the slits. Therefore, the illustrated absorption layer 20 is configured by arranging a multiplicity of film sections, which are constituent parts of the absorption layer, in a predetermined cycle in the horizontal direction of the figure to define slits extending in the direction toward the other side of the plane of the drawing.

The period of such slits forming part of a diffraction grating is adapted to the oscillation wavelength of light of a fundamental mode. More specifically, the diffraction grating is formed using a slit period which provides an oscillation wavelength in accordance with an equivalent refractive index of the fundamental mode. That is, the absorption layer 20 is provided in the form of a diffraction grating having a period associated with the oscillation wavelength of the light of a fundamental mode. Specifically, when the absorption layer 20 is, for example, an In0.08Ga0.92As film (with a band gap wavelength of 950 nm) having a thickness of 20 nm, the diffraction grating may be formed with a slit period of pitch of 137 nm in accordance with an equivalent refractive index of 3.434 of the fundamental mode. Obviously, the slit period shown here is merely a specific example.

A relationship between oscillation wavelengths and equivalent refractive indices of light and a relationship between oscillation wavelengths of light and the period of a diffraction grating will now be described with reference to specific examples.

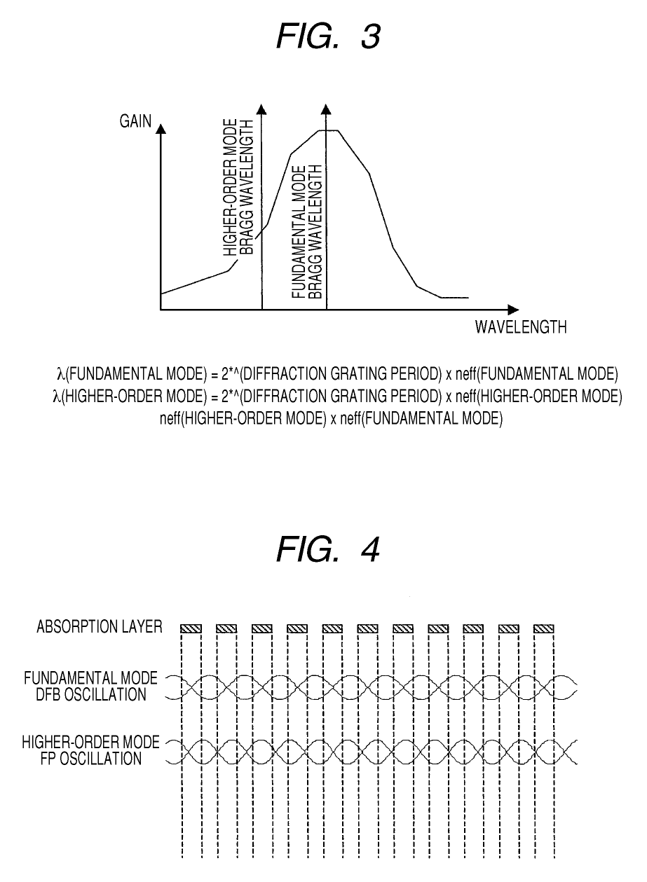

FIG. 3 is a graph showing a specific example of a relationship between oscillation wavelengths and equivalent refractive indices of light, and FIG. 4 is an illustration showing a relationship between oscillation wavelengths of light and the period of a diffraction grating.

In general, light of a fundamental mode and light of a higher-order mode have different equivalent refractive indices. An equivalent refractive index is a numerical value representing a standardized relationship between a propagation constant of light propagating in an optical waveguide and the number of waves.

When a diffraction grating has a period which is close to a wavelength of light, beams having the wavelength are strongly reflected, and such a wavelength is referred to as “Bragg wavelength”. Let us assume that a Bragg wavelength is represented by λ; a diffraction grating period is represented by Λ; and an equivalent refractive index is representedby neff. Then, the Bragg wavelength λ is given by an equation “λ=2×Λ×neff”.

It will be understood from the above that light of a fundamental mode and light of a higher-order mode have different Bragg wavelengths as shown in FIG. 3.

Therefore, when the diffraction grating period of the absorption layer 20 is set such that the Bragg wavelength of the fundamental mode agrees with a peak of gain, oscillation of the fundamental mode is encouraged, although a sufficient oscillation gain is not obtained for the higher-order mode.

Since the period of the slits of the diffraction grating is in accordance with the oscillation wavelength of the light of a fundamental mode, when the light of a fundamental mode is oscillated, the absorption layer 20 is located at nodes of the standing wave. Thus, the absorption of light at the absorption layer 20 is minimized.

Referring to the light of a higher-order mode, even if the higher-order mode is about to be oscillated in the Fabry-PeΓrot mode in the vicinity of a peak of an oscillation gain due to the effect of reflection at an end face, since the absorption layer is located in positions which are associated with neither nodes nor anti-nodes of the standing wave. Therefore, the light is subjected to relatively significant absorption, and the oscillation of the higher-order mode is suppressed accordingly.

That is, the absorption layer 20 is provided in the form of a diffraction grating having a slit period in accordance with the oscillation wavelength of the light of a fundamental mode, and a distribution feedback is advantageously provided to light guided in the semiconductor laser apparatus 1 having such an absorption layer 20. The feedback is provided such that the oscillation wavelength of the fundamental mode agrees with a peak of gain and such that the oscillation wavelength of the higher-order mode is offset from the peak of gain, which allows stable oscillation of the fundamental mode. At this time, the higher-order mode may be oscillated in the Fabry-PeΓrot mode. In such a case, nodes of the standing wave of the fundamental mode are located in positions where the absorption layer is provided. On the contrary, nodes and anti-nodes of the standing wave of the higher-order mode are in positions unrelated to the absorption layer. The higher-order mode light is therefore subjected to relatively significant absorption, and oscillation of the same is suppressed.

Therefore, in the semiconductor laser apparatus 1 having such an absorption layer 20 in the form of a diffraction grating, the absorption layer 20 minimizes light intensity loss of light of a fundamental mode while suppressing oscillation of light of a higher-order mode. Thus, the absorption layer 20 very much preferably ensures an improvement of the light output of the semiconductor laser apparatus 1.

A description will now be made on steps of manufacturing a semiconductor laser apparatus 1 having an absorption layer 20 in the form of a diffraction grating as described above.

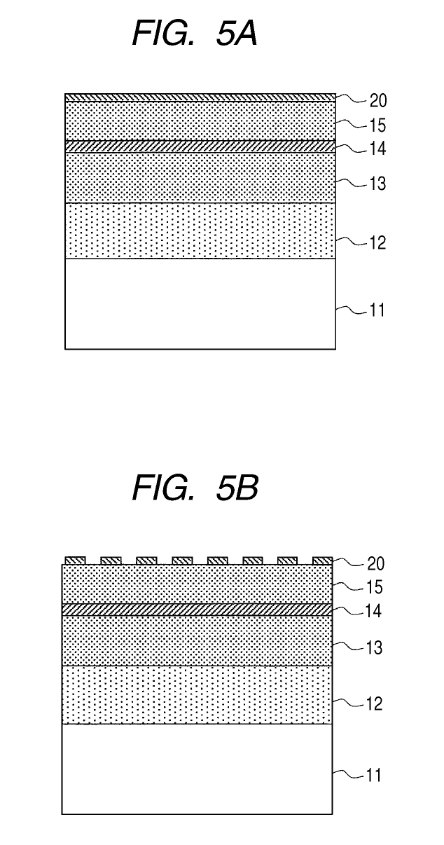

FIGS. 5A and 5B are illustrations showing an example of steps of manufacturing the semiconductor laser apparatus.

A first step of manufacturing a semiconductor laser apparatus 1 having an absorption layer 20 in the form of a diffraction grating is to form an n-clad layer 12, an n-guide layer 13, an active layer 14, a p-guide layer 15, and an absorption layer 20 in the order listed on a substrate 11 utilizing crystal growth, as shown in FIG. 5A. At this time, the absorption layer 20 may be provided in the form of a solid film.

After forming the absorption layer 20 in the form of a solid film, as shown in FIG. 5B, a diffraction grating having a slit period as described above is fabricated on the absorption layer 20 using, for example, etching. A resist pattern used for etching the diffraction grating may be fabricated using the two-beam interference exposure method. According to the method, for example, a planar beam obtained by diffusing a He—Cd laser beam using a lens is split into two beams, and the beams are overlapped with each other on a wafer surface to form interference fringes from which a periodic structure is formed.

After the absorption layer 20 in the form of a diffraction grating is formed, the p-guide layer 15, a p-clad layer 16, and a contact layer 17 are formed in the order listed utilizing crystal growth such that the absorption layer 20 will be embedded therein. A semiconductor laser apparatus 1 having a multi-layer structure as shown in FIG. 1 is obtained through the manufacturing steps described above.

The above-described embodiment represents a specific example of implementation of the invention, and the invention is not limited to the contents of the description. Specifically, the multi-layer structures, the materials, and film thicknesses of the semiconductor laser apparatus shown above as an embodiment of the invention are merely examples of the invention. It should be understood by those skilled in the art that various modifications, combinations, sub-combinations, and alterations may occur depending on design requirements and other factors insofar as they are within the scope of the appended claims or the equivalents thereof.

What is claimed is:

1. A semiconductor laser apparatus comprising:
a first clad layer;
a first guide layer;
an active layer;
a second guide layer; and
a second clad later, formed in this order,
wherein
a layer serving as an optical waveguide is formed between the first clad layer and the second clad layer and wherein the layer serving as an optical waveguide is formed with such a thickness that not only light of a fundamental mode but also light of a higher-order mode is guided, and
an absorption layer absorbing the light of a higher-order mode is formed in a position to suppress only the oscillation of the light of a higher-order mode, the absorption layer being formed as a layer forming part of the layer to serve as an optical waveguide.

2. A semiconductor laser apparatus according to claim 1, wherein the absorption layer is provided in the form of a diffraction grating having a period associated with an oscillation wavelength of the light of a fundamental mode.
